(19) United States
(12) Patent Application Publication
(10) Pub. No.: US 2011/0309461 A1
(43) Pub. Date: Dec. 22, 2011

(54) OPTICAL DETECTOR AND SPECTRUM DETECTOR

(75) Inventor: Shiro Sakai, Tokushima-shi (JP)

(73) Assignee: SEOUL OPTO DEVICE CO., LTD., Ansan-si (KR)

(21) Appl. No.: 13/203,190

(22) PCT Filed: Mar. 30, 2009
(86) PCT No.: PCT/KR2009/001597

§ 371 Date: Aug. 24, 2011

(30) Foreign Application Priority Data
Mar. 23, 2009 (JP) 2009-070541

(51) Int. Cl. H01L 31/0232; H01L 31/18

(52) U.S. Cl. 257/432; 438/71; 257/E31.127

(57) ABSTRACT

A photodetector and a spectrum detector, which can be miniaturized and do not require a complicated alignment of an optical axis, are disclosed. A photodetector comprises a substrate and a semiconductor that is formed on the substrate and has a plurality of convex portions. The photodetector detects light transmitted through the plurality of convex portions among light incident on the plurality of convex portions. Accordingly, it is possible to detect light with a specific peak wavelength without using an optical component such as a diffraction grating or prism, so that a small-sized photodetector that does not require a complicated alignment of the optical axis in an optical system may be implemented.

### CROSS REFERENCE TO RELATED APPLICATIONS

This application is the National Stage entry of International Application PCT/KR2009/001597, filed on Mar. 30, 2009, and claims priority from and the benefit of Japanese Patent Application No. 2009-070541, filed on Mar. 23, 2009, which is incorporated herein by reference for all purposes as if fully set forth herein.

### BACKGROUND OF THE INVENTION

1. Field of the Invention

The present invention relates to a photodetector and a spectrum detector, and more particularly, to a photodetector and a spectrum detector, each having concavo-convex patterns formed on a semiconductor device.

2. Discussion of the Background

In general, a diffraction grating is frequently used to implement a spectroscopic analysis of light with respect to wavelengths for the purpose of measuring the spectra of light exiting a light source. The diffraction grating is formed to have 1200 to 1600 gratings (slits) per millimeter. If the diffraction grating is rotated about an axis of the diffraction grating, light of a specific wavelength is incident onto one slit. Both ends of the grating are machined so that their angles are not constant.

Recently, a small-sized wavelength spectrometer using such a diffraction grating and a charge-coupled device (CCD) has been produced. The wavelength spectrometer requires a considerable distance between the diffraction grating and the CCD. A visible wavelength spectrometer generally has a size of 5 cm×10 cm×3 cm or so.

### SUMMARY OF THE INVENTION

An object of the present invention is to provide a photodetector and a spectrum detector, which can be miniaturized and do not require a complicated alignment of an optical axis.

According to an aspect of the present invention, there is provided a photodetector comprising: a substrate; and a semiconductor formed on the substrate, the semiconductor having a plurality of convex portions.

According to an aspect of the present invention, there is provided a photodetector comprising: a substrate; and a semiconductor formed on the substrate, the semiconductor having a plurality of convex portions, wherein the photodetector detects light transmitted through the plurality of convex portions among light incident on the plurality of convex portions.

According to an aspect of the present invention, there is provided a photodetector comprising: a substrate; and a semiconductor formed on the substrate, the semiconductor having a plurality of convex portions, wherein the photodetector allows light to be incident on the plurality of convex portions and detects light transmitted through the plurality of convex portions.

The photodetector may be provided with a plurality of photodetectors.

The convex portions may be arranged in a stripe shape in the semiconductor.

According to an aspect of the present invention, there is provided a spectrum detector comprising a plurality of photodetectors, each photodetector including a substrate and a semiconductor formed on the substrate, the semiconductor having a plurality of convex portions, wherein at least one of widths, pitches and heights of the convex portions of the plurality of photodetectors are different from one another, and the spectrum detector detects light transmitted through the plurality of convex portions among light incident on the plurality of convex portions.

The convex portions may be arranged in a stripe shape in the semiconductor.

The plurality of photodetectors may be disposed to be overlapped with one another.

According to the present invention, it is possible to detect light with a specific peak wavelength without using an optical component such as a diffraction grating or prism, so that a small-sized photodetector that does not require a complicated alignment of the optical axis in an optical system may be implemented.

### BRIEF DESCRIPTION OF THE DRAWINGS

FIG. 1 shows schematic configuration views of a photodetector 1000 according to an embodiment of the present invention, wherein FIG. 1 (A) is a plan view of the photodetector 1000 while FIG. 1 (B) is a sectional view taken along line X-X′ of FIG. 1 (A).

FIG. 2 is a view showing a configuration of a substrate portion 1001 of the photodetector 1000 according to the embodiment of the present invention.

FIG. 3 (A) and FIG. 3 (B) are views illustrating a state that light is incident on the photodetector 1000 according to the embodiment of the present invention.

FIG. 4 is a graph showing a result obtained by measuring a potential difference between a p-type electrode and an n-type electrode using a voltmeter 1010 when light (λ ranging from 200 nm to 500 nm) from a xenon lamp is incident on the photodetector 1000, an incident angle θ is changed ranging from 19° to 39° with a step of 1°, and another incident angle φ is changed ranging from 0° to 360° according to the embodiment of the present invention.

FIG. 5 is a graph showing a result for the wavelength distribution of optical voltage obtained by spectrum-analyzing data related with minimum and maximum values of the optical voltage when the incident angle θ is 20° with respect to the photodetector 1000 according to the embodiment of the present invention.

FIG. 6 is a graph showing a result obtained by calculating the difference (voltage difference) between a wavelength distribution 5001 of the optical voltage at an incident angle of φ=80° and a wavelength distribution 5003 of the optical voltage at an incident angle of φ=40° with respect to the photodetector 1000 according to the embodiment of the present invention.

FIG. 7 is a plan view of the photodetector 1000 according to the embodiment of the present invention.

FIG. 8 shows sectional views illustrating a fabrication process of the photodetector 1000 according to the embodiment of the present invention.

FIG. 9 shows sectional views illustrating a fabrication process of the photodetector 1000 according to the embodiment of the present invention.

FIG. 10 shows sectional views illustrating a fabrication process of the photodetector 1000 according to the embodiment of the present invention.

FIG. 11 is a schematic configuration view of a spectrum detector 2000 according to an embodiment of the present invention.

FIG. 12 is a schematic view of the configuration of a spectrum detector 3000 according to an embodiment of the present invention.

FIG. 13 is a schematic view of the configuration of a photodetector 4000 according to an embodiment of the present invention.

### DETAILED DESCRIPTION OF THE ILLUSTRATED EMBODIMENTS

Hereinafter, embodiments of the present invention will be described in detail with reference to the accompanying drawings. In addition, each embodiment described below is merely one form of the present invention, and the present invention is not limited to these embodiments.

### Embodiment 1

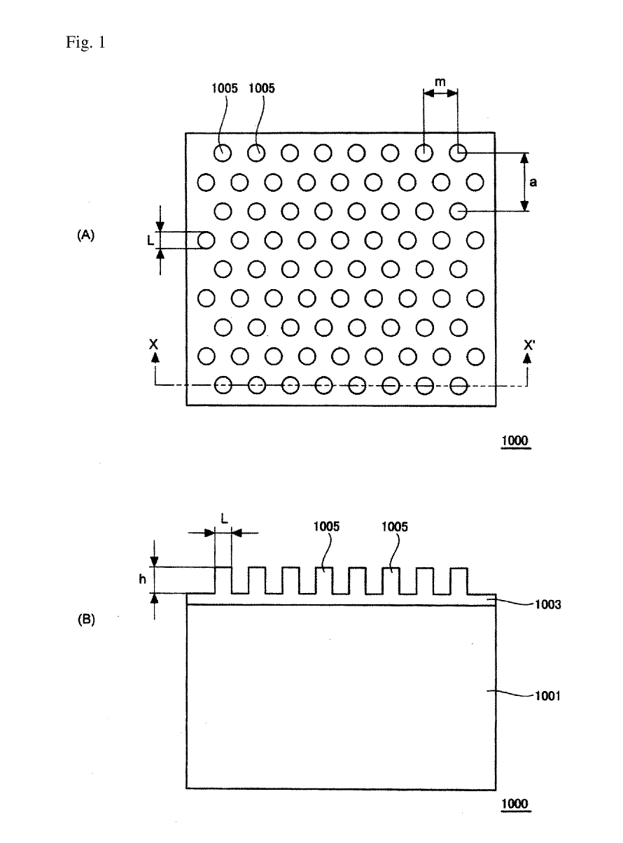

FIG. 1 is a schematic view of the configuration of a photodetector 1000 according to an embodiment of the present invention. FIG. 1 (A) is a plan view of the photodetector 1000 while FIG. 1 (B) is a sectional view taken along line X-X′ of FIG. 1 (A). The photodetector 1000 has a substrate portion 1001 and a semiconductor layer 1003. As shown in FIG. 1 (A) and FIG. 1 (B), the semiconductor layer 1003 of the photodetector 1000 has a plurality of convex portions 1005. The convex portions 1005 are arranged according to a predetermined rule. A concavo-convex pattern formed by the convex portions 1005 is referred to as “a nano-pattern.” In this embodiment, each of the convex portions 1005 is shaped as a cylinder with a diameter ‘L’ and a height ‘h,’ and the convex portions 1005 are arranged to have a short pitch (short period) of ‘m’ and a long pitch (long period) of ‘a’ as shown in FIG. 1 (A). Further, a cylindrical convex portion is used as the convex portion 1005 in this embodiment, but the present invention is not limited thereto. For example, the convex portion may be variously shaped as a polyprism, a cone and a triangular pyramid. Nevertheless, it is preferable that the difference between concave and convex portions in the concavo-convex pattern is adjusted so as not to be increased so much when the shape of each convex portion 1005 is selected. Further, each of the convex portions 1005 is disposed to be positioned at an apex of a regular triangle in this embodiment, but the present invention is not limited thereto.

In this embodiment, each convex portion 1005 has a diameter L=150 nm, a height h=70 nm, a short pitch m=300 nm, and a long pitch a=√3×300≈520 nm, but the present invention is not limited thereto.

FIG. 2 is a view showing a configuration of a substrate portion 1001 in the photodetector 1000 according to the embodiment of the present invention. In this embodiment, the substrate portion 1001 has the same structure as a light emitting diode (LED) using a GaN-based compound semiconductor. Specifically, in this embodiment, the substrate portion 1001 is formed by sequentially stacking a GaN buffer layer 1001b with a thickness of 25 nm, an u-GaN layer 1001c with a thickness of 500 nm, an n-type GaN clad layer 1001d with a thickness of 2 μm, In_{0.05}Ga_{0.95}N quantum well active layer 1001e with a thickness of 2 nm and a p-type Al_{0.20}Ga_{0.80}N layer 1001f with a thickness of 30 nm on a sapphire substrate 1001a. In this embodiment, a p-type GaN layer 1003 with a thickness of 110 nm is formed on the p-type Al_{0.20}Ga_{0.80}N layer 1001f of the substrate portion 1001. Further, the substrate portion 1001 uses the structure as described above in this embodiment, but the present invention is not limited thereto.

In addition, the p-type gallium nitride layer (p-type GaN layer) 1003 with a thickness of 110 nm is formed on the substrate portion 1001 in this embodiment, but the present invention is not limited thereto. For example, a GaN-based semiconductor such as n-type GaN or AlₓGa₁₋ₓN may be used. If n-type GaN is used as the semiconductor layer 1003, a schottky barrier may be used. If n-type GaN or n-type InGaAlN (only, a carrier concentration of the n-type material <5×10¹⁷ cm³)is used, light can be sensed not only in a p-n junction portion but also in an n-type semiconductor layer. Photovoltaic photodetectors are classified into a p-n junction photodetector and an n-type schottky photodetector. In the n-type schottky photodetector, the n-type material requires a low carrier concentration (a carrier concentration of the n-type material <5×10¹⁷ cm³ or I-layer). The I-layer refers to a layer in which there is no carrier, wherein an undoped layer is referred to as the I-layer in many cases. Specifically, a layer in which carriers are removed by dislocations such as in a GaN layer, and a layer in which carriers are removed using a p-type dopant may be also referred to as the I-layer. Similarly, a layer in which carriers are removed by introducing an n-type dopant to a p-type semiconductor may be also referred to as the I-layer.

A fabricating method of the convex portions 1005 of the p-type GaN layer 1003 will be described later. By etching a portion of the p-type Al_{0.20}Ga_{0.80}N layer 1001f, the convex portions 1005 may be formed by the portion of the p-type Al_{0.20}Ga_{0.80}N layer 1001f and the p-type GaN layer 1003.

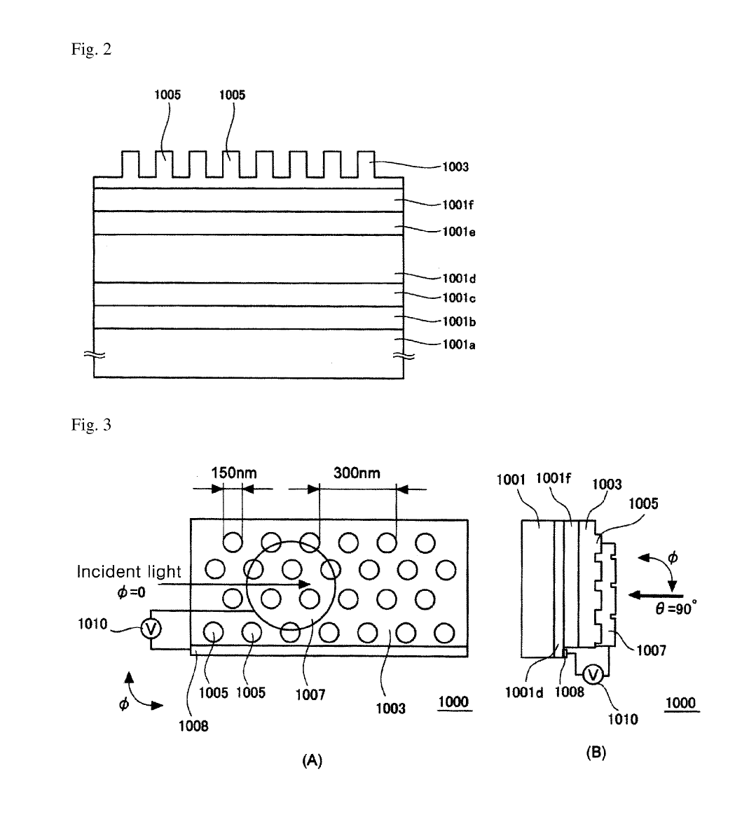

Next, an operation of the photodetector 1000 according to the embodiment of the present invention will be described with reference to FIGS. 3 to 7. FIG. 3 (A) and FIG. 3 (B) are views illustrating a state that light is incident on the photodetector 1000 according to the embodiment of the present invention. In this embodiment, an incident angle of the incident light with respect to the short-pitch direction of the convex portions 1005 of the p-type GaN layer 1003 is defined as φ, while another incident angle of the incident light with respect to a surface of the p-type GaN layer 1003 is defined as θ. The incident angle which is parallel to the short-pitch direction is defined as φ=0, and the incident angle which is vertical to the surface of the p-type GaN layer 1003 is defined as θ=90°. In the photodetector 1000 according to this embodiment of the present invention, the light from a light source is incident on sides and surfaces of the convex portions 1005.

To identify the operation of the photodetector 1000 according to this embodiment, a p-type electrode was formed by forming a Ni and Au layer 1007 on the GaN-based semiconductor layer (p-type GaN layer) 1003 (see FIG. 3 (A) and FIG. 3 (B)). An n-type electrode was formed by etching a portion of the photodetector until the n-type GaN layer 1001d is exposed and then forming a Ti and Al layer 1008 on the etched portion. The potential difference (optical voltage) between a p-type electrode and an n-type electrode is measured by a voltmeter 1010. In addition, the other layers except the n-type GaN layer 1001d and the p-type Al_{0.20}Ga_{0.80}N layer 1001f in the substrate 1001 are omitted in FIG. 3 (B) for convenience of illustration.

When light (λ ranging from 200 nm to 500 nm) from a xenon lamp is incident on the photodetector 1000 according to this embodiment, the incident angle θ is changed ranging from 19° to 39° with a step of 1°, and the incident angle φ is changed ranging from 0° to 360°, the potential difference between the p-type electrode and the n-type electrode was measured by the voltmeter 1010.

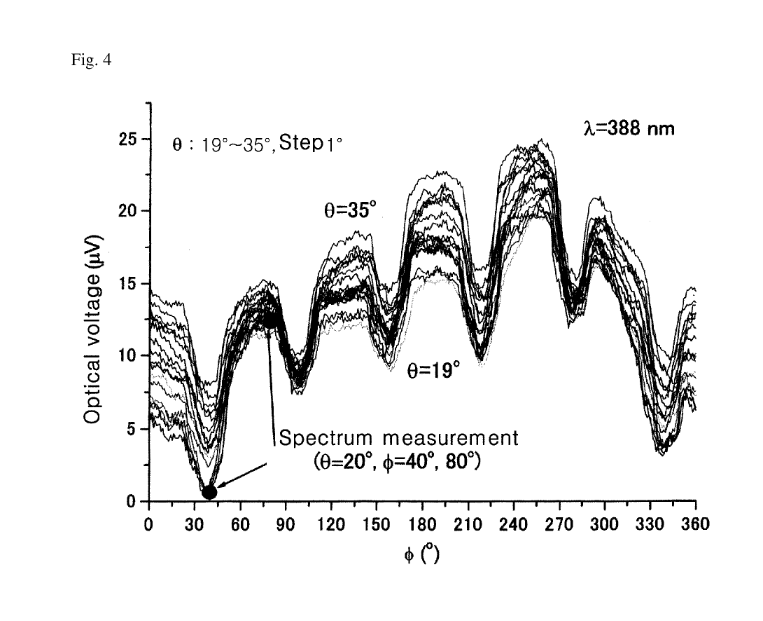

The measured result is shown in FIG. 4. FIG. 4 shows the measured result of the is potential difference (optical voltage) between the p-type electrode and the n-type electrode of the photodetector 1000 when λ=388 nm. As shown in FIG. 4, it can be seen that whenever the incident angle θ is changed from 19° to 39°, the optical voltage is changed to have a plurality of minimum and maximum values with respect to the change in the incident angle φ.

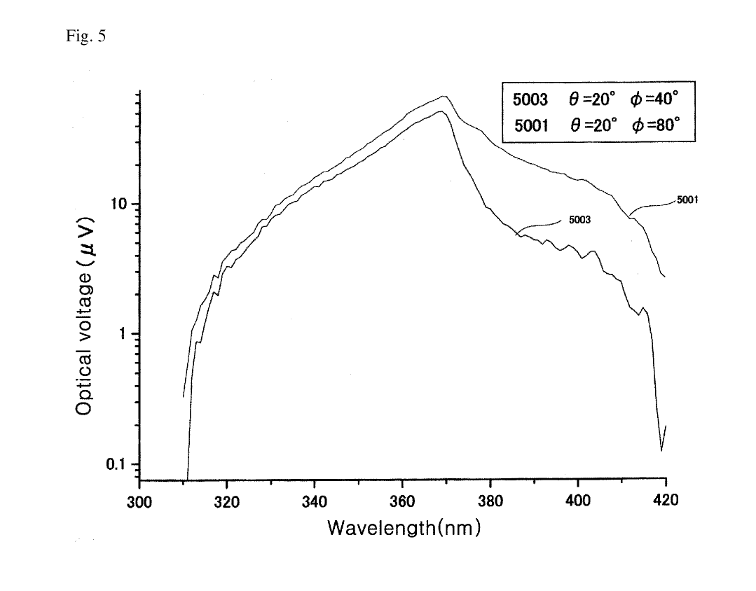

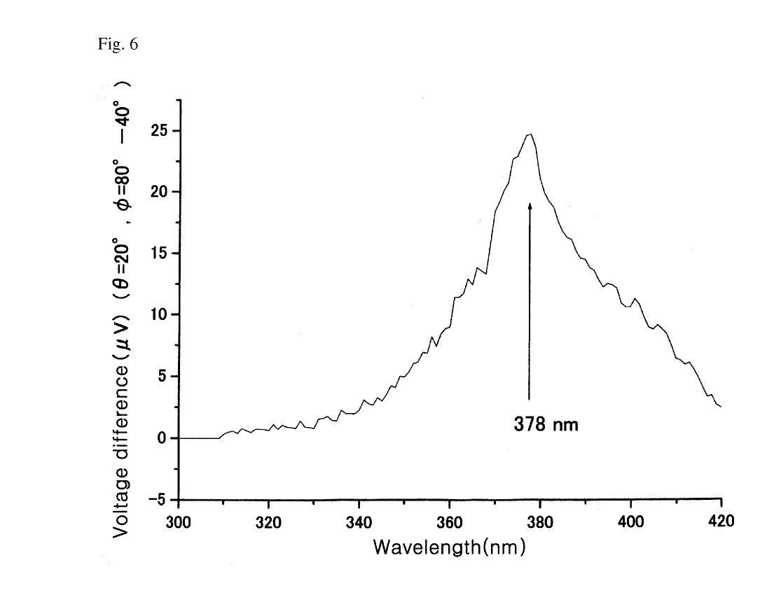

FIG. 5 shows a result for the wavelength distribution of optical voltages obtained by spectrum-analyzing data related with the minimum and maximum values (of points designated by in FIG. 4, the incident angle φ=40° and 80°) of the optical voltages when the incident angle θ is 20°. FIG. 6 shows a result obtained by calculating the difference (voltage difference) between the wavelength distribution 5001 of optical voltages at an incident angle of φ=80° and the wavelength distribution 5003 at an incident angle of φ=40°. As shown in FIG. 6, the voltage difference is maximum when the wavelength λ=378 nm. Thus, it can be seen that the photodetector 1000 according to this embodiment most poorly absorbs the incident light with a wavelength λ=378 nm, i.e., most well detects the incident light. In other words, the photodetector 1000 according to this embodiment detects incident light with a specific peak wavelength of λ=378 nm among the whole light incident thereon. Therefore, if light is incident on the photodetector 1000 according to this embodiment and transmitted light is detected by applying the principle as described above, it can be visually identified whether or not the light has a specific peak wavelength of λ=378 nm. Thus, it is possible to detect light with a specific peak wavelength without using an optical component such as a diffraction grating or prism, so that a small-sized photodetector that does not require a complicated alignment of the optical axis in an optical system may be implemented.

Since each convex portion 1005 in the photodetector 1000 according to this embodiment has a diameter L=150 nm, a short pitch m=300 nm, a long pitch a=520 nm and a height h=70 nm, it is considered that light with a specific peak wavelength of λ=378 nm is detected. In the photodetector 1000 according to this embodiment, the diameter L, the short pitch m, the long pitch a and the height h of the convex portion 1005 is correlated with a specific peak wavelength λ of the detected light. That is, light with a peak wavelength of λ=378 k nm can be detected by multiplying the diameter L of each convex portion by k times.

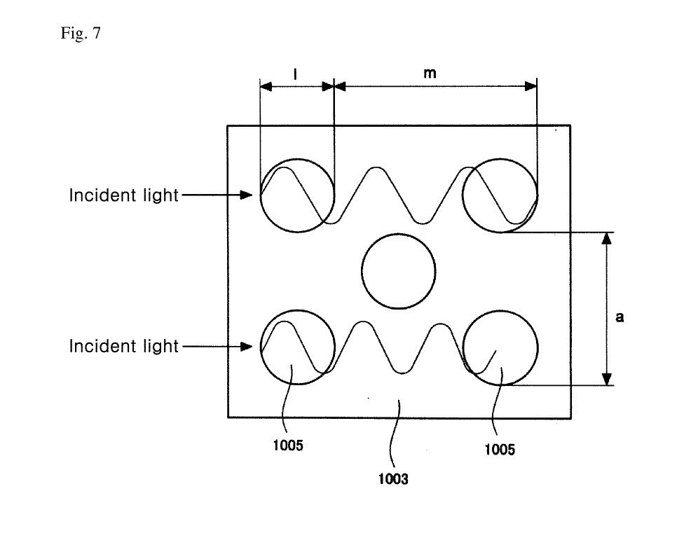

Next, the photodetector according to this embodiment will be described with reference to FIG. 7. FIG. 7 is a plan view of the photodetector 1000 according to the embodiment of the present invention, in which a relationship between the diameter L and the short pitch m of the convex portion 1005 and incident light is shown when the incident angle is θ. In the photodetector 1000 according to this embodiment, the above relationship may be expressed by the following formula (1):

L·m=λ·cos θ/(2n) (1)

where L denotes a diameter of each convex portion 1005, m denotes a wave number, and n denotes a refractive index (between the air and each convex portion 1005 (nano-pattern) of the GaN layer 1003), 1<n<2.6 (the refractive index of GaN), and m is an integer or a reciprocal of an integer. At this time, n is defined as a refractive index (between the air and the nano-pattern) because a nano-structure cannot be viewed with the naked eye (400 nm<visible wavelength (visible light)<700 nm, wherein a structure having a size ranging from 1 nm to 1 μm is generally referred to as a nano-structure).

Parameters of this embodiment, i.e., the diameter L=150 nm of the convex portion 1005, λ=378 and θ=20° may be inputted in the formula (1) to obtain the following formula (2):

n·m=1.187 (2)

In the formula (2), n=1.187 when m=1, while n=2.37 when m=½. Thus, an appropriate numerical value can be obtained using the refractive index n between the air and the GaN nano-pattern.

In the photodetector 1000 according to this embodiment, incident light is guided onto the convex portions 1005 so that a specific wavelength component may be absorbed, thereby generating light with a specific peak wavelength.

Formation of Convex Portions 1005 (Nano-Patterns)

Next, a fabricating method of the photodetector 1000 according to this embodiment, particularly, a fabricating method of the convex portions 1005 will be described.

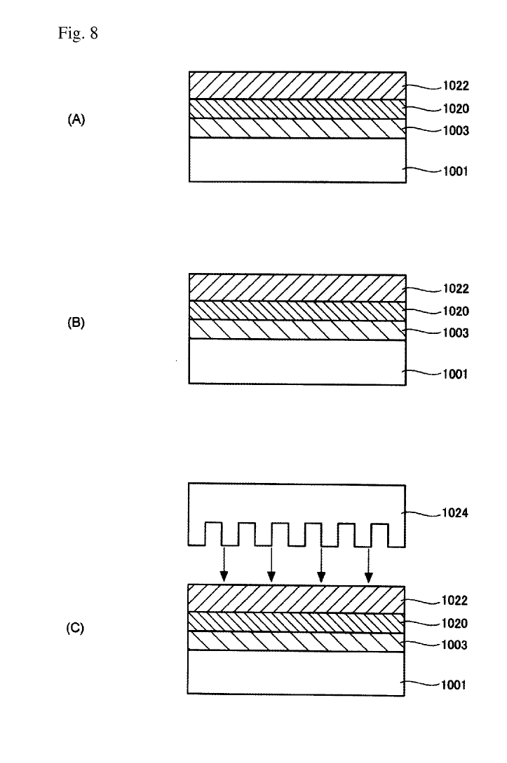

As shown in FIG. 8 (A), after a GaN layer 1003 is formed on a substrate portion 1001, a Ni layer 1020 with a thickness of 10 nm is deposited on the GaN layer 1003 using an electron beam (EB) deposition technique, and a thermosetting resin 1022 is applied on the Ni layer. Then, the thermosetting resin 1022 is softened by increasing the entire temperature (see FIG. 8 (B)). Subsequently, a nano-pattern is transferred to the thermosetting resin 1022 by pressing a mold 1024 with a desired pattern (nano-pattern) structure onto the thermosetting resin 1022 (see FIG. 8 (C)).

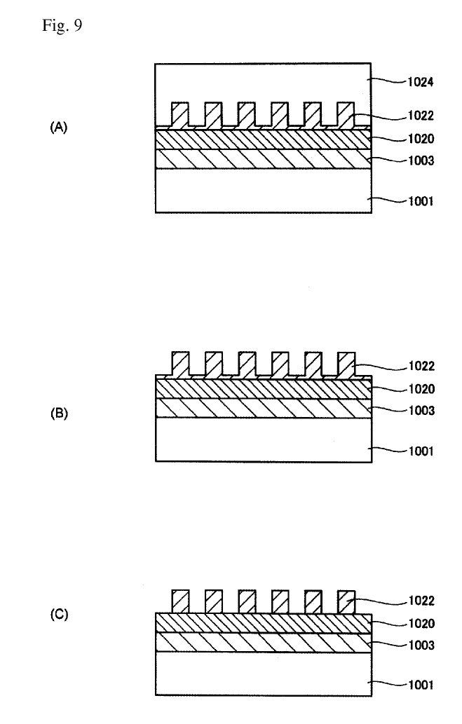

Subsequently, the thermosetting resin 1022 is cured by cooling the entire structure while the nano-pattern is transferred onto the thermosetting resin 1022 by the mold (see FIG. 9 (A)). Then, the mold 1024 is separated from the thermosetting resin 1022 (see FIG. 9 (B)). Subsequently, a residual film of the thermosetting resin 1022 is removed by performing the UV-O₃ treatment (see FIG. 9 (C)). At this time, the mold pattern of the thermosetting resin 1022 is slightly etched.

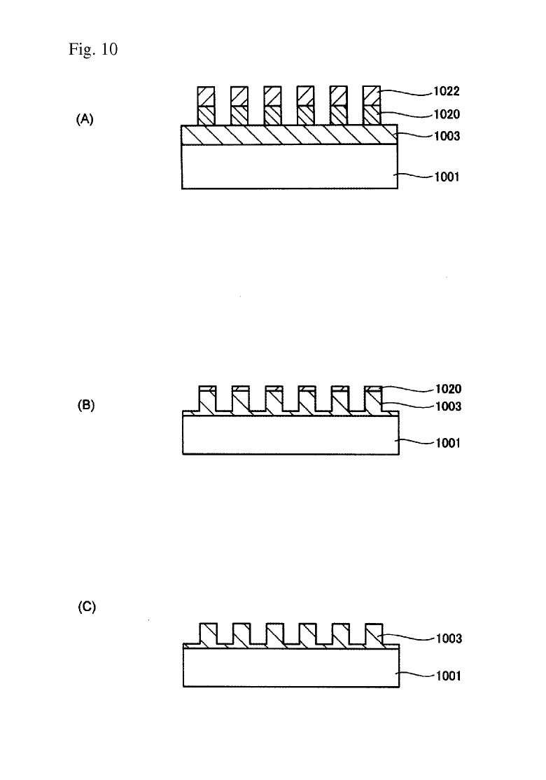

Subsequently, the nano-pattern is formed in the Ni-layer 1020 by etching the Ni layer 1020 through reactive ion etching (RIE) using Ar gas (see FIG. 10 (A)). Then, the nano-pattern is formed in the GaN layer 1003 by etching the GaN layer 1003 through the RIE using BCl₃ and Cl₂ gas (see FIG. 10 (B)). Subsequently, the nano-pattern may be formed in the GaN layer 1003 by removing the Ni layer 1020 using a 5% HNO₃ solution (see FIG. 10 (C)). By etching a portion of p-type Al_{0.20}Ga_{0.80}N layer 1001f in the substrate portion 1001 through an appropriate change in etching conditions, the convex portions 1005 may be formed by the p-type GaN layer 1003 and the portion of the p-type Al_{0.20}Ga_{0.80}N layer 1001f.

Through the photodetector according to this embodiment, it is possible to detect light with a specific peak wavelength without using an optical component such as a diffraction grating or prism, so that a small-sized photodetector that does not require a complicated alignment of the optical axis in an optical system may be implemented.

### Embodiment 2

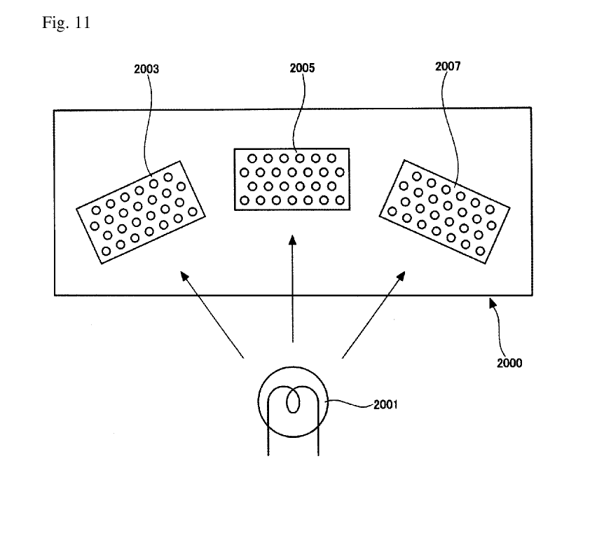

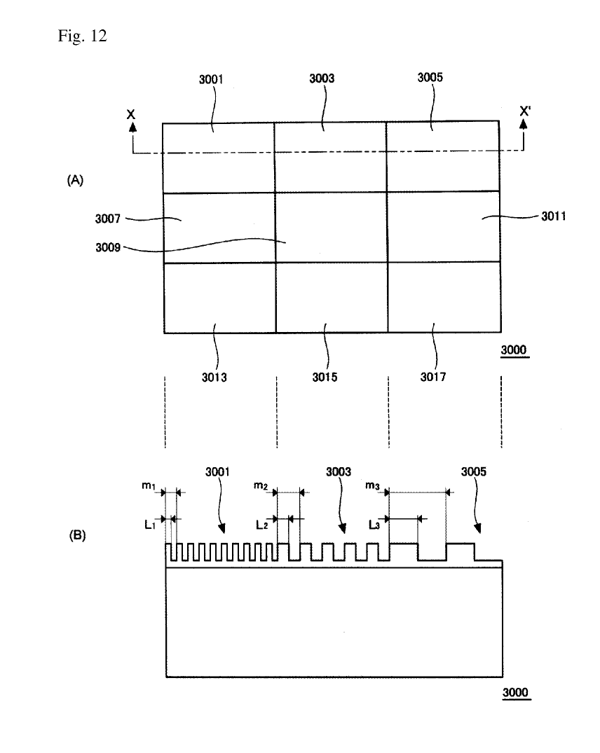

In this embodiment, a spectrum detector having a plurality of photodetectors according to the present invention will be described. FIG. 11 shows a schematic configuration of a spectrum detector 2000 according to an embodiment of the present invention. The spectrum detector 2000 according to this embodiment comprises photodetectors 2003, 2005 and 2007 each having the same configuration as the photodetector 1000 described in the Embodiment 1. In this embodiment, the spectrum detector having three photodetectors according to the present invention is described as an example, but the number of photodetectors is not limited thereto. That is, a high-precision spectrum detector can be implemented by providing a larger number of photodetectors.

In the spectrum detector 2000 according to this embodiment, the photodetectors 2003, 2005 and 2007 are photodetectors for detecting light having different peak wavelengths from one another, respectively. Each of the photodetectors for detecting light having different peak wavelength from one another may be implemented by properly setting the diameter L, the short pitch m, the long pitch a and the height h of each of the convex portions 1005, as described above in Embodiment 1. In this embodiment, the photodetector 2003 is a detector (L=150 nm) for detecting light having a peak wavelength λ=378 nm, and the photodetector 2005 is a detector (L=140 nm) for detecting light having a peak wavelength λ=353 nm. The photodetector 2007 is a detector (n=160 nm) for detecting light having a peak wavelength λ=403 nm is detected.

Light exiting from light source 2001 is incident on the spectrum detector 2000 and then incident on the photodetectors 2003, 2005 and 2007. Since each of the photodetectors 2003, 2005 and 2007 detects light having a specific peak wavelength, the spectrum distribution of the light source 2001 can be identified by viewing the detected light through the photodetectors 2003, 2005 and 2007.

As described above, it is possible to easily identify the spectrum distribution of the light source through the spectrum detector 2000 according to this embodiment.

In the spectrum detector 2000 according to this embodiment, the photodetectors 2003, 2005 and 2007 may be disposed to be overlapped with one another. If a GaN-based semiconductor layer is used for the photodetectors 2003, 2005 and 2007, a spectrum detector ranging from a wavelength of 360 nm to the wavelength of InGaN (360 nm to 600 nm) is configured. If the photodetectors 2003, 2005 and 2007 are disposed to be overlapped with each other, Si or GaAs cannot be used as a substrate of the photodetector due to the light absorption of the substrate. Since the thickness of the substrate is 300 μm or so, a spectrum detector with a wavelength ranging from 550 nm to 850 nm can be implemented in an epitaxial GaAs on a GaP substrate. In the epitaxial GaAs on the GaP substrate, a photodetector can be formed by inserting an etching stop layer into another substrate (GaAs), forming an active layer and then positioning the entire structure on the GaP substrate after the growth.

### Embodiment 3

In this embodiment, another example of the spectrum detector having a plurality of photodetectors according to the present invention will be described. FIG. 12 (A) and FIG. 12 (B) show a schematic configuration of a spectrum detector 3000 according to the embodiment of the present invention. The spectrum detector 3000 according to this embodiment comprises photodetectors 3001, 3003, 3005, 3007, 3009, 3011, 3013, 3015 and 3017 formed on one sapphire substrate. Here, each of the photodetectors has the same configuration as the photodetector 1000 described in Embodiment 1. In this embodiment, the spectrum detector having nine photodetectors according to the present invention is described as an example, but the number of photodetectors is not limited thereto. That is, a high-precision spectrum detector can be implemented by providing a larger number of photodetectors.

In the spectrum detector 3000 according to this embodiment, the photodetectors 3001, 3003, 3005, 3007, 3009, 3011, 3013, 3015 and 3017 are photodetectors for detecting light having different peak wavelengths from one another, respectively. Each of the photodetectors for detecting light having different peak wavelengths from one another may be implemented by properly setting the diameter L, the short pitch m, the long pitch a and the height h of each of the convex portions 1005, as described in Embodiment 1. FIG. 12 (B) is a sectional view of the spectrum detector 3000 taken along line X-X′. As shown in FIG. 12 (B), the photodetector 3001 has a nano-pattern with a pitch m₁ and a diameter L₁ of its convex portion, the photodetector 3003 has a nano-pattern with a pitch m₂ and a diameter L₂ of its convex portion, and the photodetector 3005 has a nano-pattern with a pitch m₃ and a diameter L₃ of its convex portion. Similarly, the photodetectors 3007, 3009, 3011, 3013, 3015 and 3017 also have nano-patterns with different pitches m and/or different diameters L of their convex portion, respectively. In the spectrum detector 3000 according to this embodiment, light having different peak wavelengths from one another can be detected by appropriately adjusting the diameter L, the short pitch m, the long pitch a and the height h. Thus, in the spectrum detector 3000 according to this embodiment, it is possible to easily identify the spectrum distribution of the light source.

### Embodiment 4

In this embodiment, a photodetector having convex portions with a different shape from those of Embodiments 1 to 3 will be described.

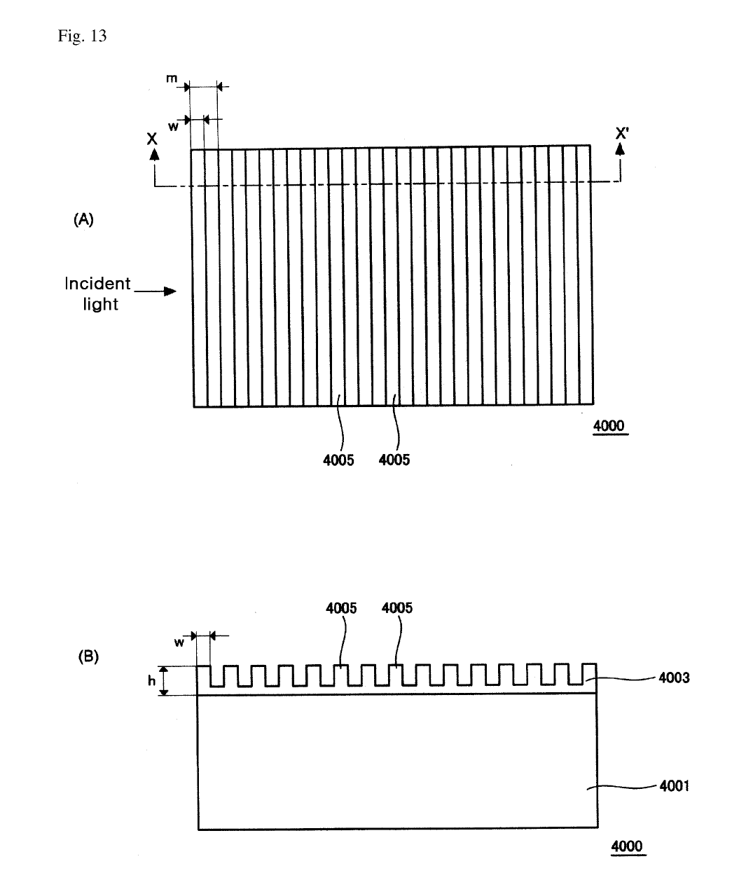

FIG. 13 (A) is a plan view of a photodetector 4000 according to an embodiment of the present invention and FIG. 13 (B) is a sectional view of the photodetector 400 taken along line X-X′. The photodetector 4000 has a substrate portion 4001 and a GaN-based semiconductor layer 4003. As shown in FIG. 13 (A) and FIG. 13 (B), the GaN-based semiconductor layer 4003 of the photodetector 4000 has a plurality of convex portions 4005. The convex portions 4005 are arranged in a stripe shape according to a predetermined rule. In this embodiment, the convex portion 4005 has a rectangular parallelepiped shape (rectangular shape) with a width w and a height h. As shown in FIG. 13 (A), the convex portions are arranged with a pitch (period) m. Other configurations are identical to those of the aforementioned Embodiment 1, and therefore, their descriptions will be omitted.

In the photodetector 4000 according to this embodiment, incident light from a light source is incident in parallel to a direction which is vertical to a sidewall of the rectangular-parallelepiped-shaped convex portion 4005, so that it is possible to detect light with a specific peak wavelength depending on the width w, the height h and the pitch m of the convex portions, as described in Embodiment 1.

### Embodiment 5

In the aforementioned Embodiments 1 to 4, the GaN-based semiconductor is used as the nano-pattern and the substrate. However, the photodetector and the spectrum detector of the present invention are not limited thereto, but other semiconductors such as Si-based and GaAs-based semiconductors may be used.

1. A photodetector, comprising:
a substrate; and
a semiconductor formed on the substrate, the semiconductor comprising a plurality of convex portions.

2. The photodetector of claim 1,
wherein the photodetector detects light transmitted through the plurality of convex portions.

3. The photodetector of claim 1,
wherein light incident on the plurality of convex portions is detected through the plurality of convex portions without using diffraction grating or a prism.

4. The photodetector of claim 3, wherein the photodetector comprises a plurality of photodetectors.

5. The photodetector of claim 3, wherein the convex portions are arranged in a stripe shape in the semiconductor.

6. A spectrum detector, comprising:
a plurality of photodetectors, each photodetector comprising a substrate; and a semiconductor formed on the substrate, the semiconductor comprising a plurality of convex portions,
wherein at least one of widths, pitches, and heights of the convex portions of the plurality of photodetectors is different from another one of the widths, pitches, and heights of the convex portions, and the spectrum detector detects light transmitted through the plurality of convex portions.

7. The spectrum detector of claim 6, wherein the convex portions are arranged in a stripe shape in the semiconductor.

8. The spectrum detector of claim 7, wherein photodetectors in the plurality of photodetectors overlap each other.

9. The photodetector of claim 1, wherein each of the convex portions is disposed at an apex of a regular triangle.

10. The spectrum detector of claim 6, wherein a spectrum distribution of the detected light is identified by configuring the plurality of photodetectors to detect the detected light at different wavelengths.

11. The photodetector of claim 1, wherein a convex portion transmits light according to a height, a width, and a pitch of the convex portion.

12. A method to fabricate a photodetector, the method comprising:
forming a resin on a substrate;
forming a nano-pattern by transferring a nano-pattern on the resin using a mold;
cooling the nano-pattern;
etching the nano-pattern and the substrate,
wherein etching the substrate comprises partially removing at least two layers of the substrate.

13. The method of claim 12,
wherein the substrate comprises:
a first layer;
a gallium-nitride (Ga—N) layer disposed on the first layer; and
a nickel (Ni) layer disposed on the Ga—N layer, and
wherein etching the substrate further comprises:
etching the Ga—N layer and the Ni layer using reactive ion etching.

14. The method of claim 13, wherein convex portions comprise the first layer and the Ga—N layer, and
wherein the convex portions is formed by etching, at least partially, the first layer and the Ga—N layer.
